(19) United States
(12) Patent Application Publication
(10) Pub. No.: US 2013/0062195 A1
(43) Pub. Date: Mar. 14, 2013

(54) PROCESS FOR PREPARATION OF CARBON NANOTUBES FROM VEIN GRAPHITE

(71) Applicants: Lilantha Samaranayake, Kandy (LK); Nilwala Kottegoda, Horana (LK); Asurasinghe R. Kumarasinghe, Nugegoda (LK); Ajith De Alwis, Thalawatugoda (LK); Sunanda Gunasekara, Piliyandala (LK); Sameera Nanayakkara, Harrispaththuwa (LK); Veranja Karunaratne, Kandy (LK)

(72) Inventors: Lilantha Samaranayake, Kandy (LK); Nilwala Kottegoda, Horana (LK); Asurasinghe R. Kumarasinghe, Nugegoda (LK); Ajith De Alwis, Thalawatugoda (LK); Sunanda Gunasekara, Piliyandala (LK); Sameera Nanayakkara, Harrispaththuwa (LK); Veranja Karunaratne, Kandy (LK)

(73) Assignee: Sri Lanka Institute of Nanotechnology (PVT) Ltd., Walgama (LK)

(21) Appl. No.: 13/590,626

(22) Filed: Aug. 21, 2012

Related U.S. Application Data
(63) Continuation-in-part of application No. 12/766,888, filed on Apr. 25, 2010, now abandoned.

(51) Int. Cl. C23C 14/24; B82Y 99/00; B82Y 40/00

(52) U.S. Cl. 204/192.38; 204/298.41; 977/844; 977/750

(57) ABSTRACT

A catalyst free process for manufacturing carbon nanotubes by inducing an arc discharge from a vein graphite anode and a vein graphite cathode in an inert gas atmosphere contained in a closed vessel. The process is carried out at atmospheric pressure in the absence of external cooling mechanism for the carbon cathode or the carbon anode.

### CROSS-REFERENCE TO RELATED APPLICATIONS

This application is a continuation-in-part of U.S. application Ser. No. 12/766,888 filed Apr. 25, 2010, which is hereby incorporated herein in its entirety by reference.

### FIELD OF THE INVENTION

This invention relates to the field of manufacturing single walled carbon nanotubes from vein graphite.

### BACKGROUND OF THE INVENTION

Carbon nanotubes (CNT) are long, thin cylinders of carbon, with a diameter that can be as small as 1 nm and a length that can range from a few nanometers to one or more microns. A CNT may be thought of as a sheet of graphite, i.e., a hexagonal lattice of carbon, rolled into a cylinder. A CNT may have a single cylindrical wall (SWCNT), or it may have multiple walls (MWCNT), giving it the appearance of cylinders inside other cylinders. Sumio Iijima discovered SWCNTs in 1991. (See Iijima et.al, Nature, Vol. 354(6348), p. (56-58) (1991). A SWCNT has only a single atomic layer, whereas a MWCNT may contain, for example, from 100 to 1,000 atomic layers. Generally, SWCNTs are preferred over MWCNTs because they have fewer defects and are therefore stronger. Further, SWCNTs tend to be stronger and more flexible than their multi-walled counterparts. Further, SWCNTs are also better electrical conductors and find uses in electrical connectors in micro devices such as integrated circuits or in semiconductor chips used in computers. Their unique structural and electronic properties make them attractive for applications in nanoelectronics. Depending on their chirality SWCNTs are either metallic or semiconducting. Uses of CNTs include antennas at optical frequencies, probes for scanning probe microscopy such as scanning tunneling microscopy (STM) and atomic force microscopy (AFM), and reinforcements for polymer composites.

Several techniques exist for making SWCNTs that require expensive equipment and/or the use of metal catalysts. For example, SWCNTs are currently manufactured in laboratories via laser ablation, electric-arc, or chemical vapor deposition (CVD) processes. CVD process used to grow nanotubes on patterned substrates is more suitable for the development of nanoelectronic devices and sensors. Laser ablation and electric-arc techniques tend to (i) produce SWCNTs in small amounts (milligram to gram in a few hours) and (ii) employ metal catalysts. These catalysts may be difficult to completely remove from post-production CNTs, even after extensive cleaning and purification. Electric-arc techniques also require a pressurized chamber, which can be costly and dangerous. For SWCNTs made by the DC arc discharge method using anodes and cathodes. (See generally, Zaho, et.al, J. Chem. Phys. Lett., Vol. 373, pp. 2260-2266, (2009) and Anazawa et al., 2009 U.S. Pat. No. 7,578,980 B2). In electric arc methods the anode is a carbon rod homogeneously doped with a Fe, Co or Ni catalyst and the cathode a pure carbon rod. (See Wang, et.al, J. Phys. Chem. C, Vol. 113, p. 12079-12084, (2009)). When a Ni compound or a Fe compound is included in the anode, the compound acts as a catalyst so that SWCNTs can be produced efficiently. General consensus in the art is that carbon vapor in the form of atoms, ions, or small molecules are necessary for nanotube growth with metal catalysts. (See generally, Gamaly et.al, Phys. Rev. B, Vol. 52, p. 2083-2089, (1995). It has also been proposed that ordered graphitic precursors are essential for nanotube growth (Lauerhaas, et.al, J. Mater. Res. Vol. 12, p. 1536-1544, (1997). Catalyst free process for CNTs is disclosed in Benevides et al. 2004 (U.S. Pat. No. 6,740,224B1) and Benevides 2006 (U.S. Pat. No. 7,008,605B1). Here, CNTs were produced by arc discharge and required external means to cool the graphite cathode. As SWCNTs are also more expensive to make (SWCNTs cost about $ 500/g and MWCNTs cost about $ 5/g) and the economics of scale may not change until there is a large-scale market and large scale production capability for SWCNTs. For these reasons, MWCNTs are more widely used in composite materials than SWCNTs. Given the above, there exists a need for a simple, low-cost method of manufacturing high-quality, SWCNTs that eliminates the need for extensive cleaning and purification of the CNT product.

### SUMMARY

Accordingly, disclosed herein is a catalyst free process of manufacturing carbon nanotubes comprising:
a) providing a vein graphite anode and a vein graphite cathode in the absence of a magnetic field supplying device;
b) inducing a DC electric current through the anode and the cathode in the absence of external cooling of the cathode or the anode;
c) providing an inert gas atmosphere; and
d) producing carbon nanotubes on the cathode.
   Embodiment processes provide for preparing CNTs comprising SWCNTs. A DC electric current is induced through a carbon anode and a carbon cathode under conditions effective to produce the carbon nanotubes, wherein the anode and the cathode are of substantially the same size. In an embodiment a welder is used to induce the electric current via an arc discharge process and the process does not require a pressurized chamber. In a preferred embodiment the inert gas is recycled. Also disclosed are carbon nanoparticles that are precursors to the CNT growth process.

### BRIEF DESCRIPTION OF DRAWINGS

FIG. 1. A schematic view of the arc-discharge apparatus used to prepare carbon nanotubes.

FIG. 2. Scanning Electron Microscopy (SEM) image of flake graphite from Sri Lanka.

FIG. 3. SEM image of vein graphite from Sri Lanka.

FIG. 4. SEM image of Sri Lankan vein graphite affixed to the anode and cathode prior to producing a DC arc discharge.

FIG. 5. SEM image of the vein graphite cathode after 10 s arc discharge time at 40 A of DC current.

FIG. 6. SEM image of the vein graphite cathode after 25 s arc discharge time at 40 A of DC current.

FIG. 7. SEM image of the vein graphite cathode after 30 s arc discharge time at 40 A of DC current.

FIG. 8. SEM image of the vein graphite anode after 10 s arc discharge time at 40 A of DC current.

FIG. 9. High Resolution Transmission Electron Microscopy (200 kV) image of SWCNTs prepared by the disclosed process.

### DETAILED DESCRIPTION

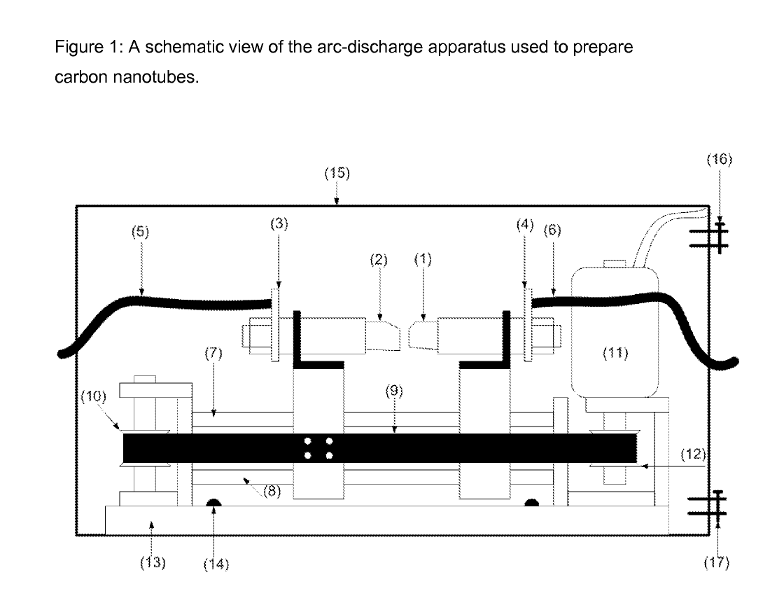

As disclosed herein application of an electric current to a vein graphite anode and a vein graphite cathode under conditions effective to produce CNTs comprising SWCNTs, is described in more detail below. See FIG. 1 for a schematic of the apparatus used in the production of CNTs. While the invention has been described in detail and with reference to specific embodiments thereof, it will be apparent to those of ordinary skill in the art that various changes and modifications can be made therein without departing from the spirit and scope thereof. The CNTs referred to herein includes SWCNTs unless specifically stated otherwise.

Cathodes and anodes described herein comprise vein graphite. Graphite is an electrical conductor and there are three types of natural graphite:
1. Flake graphite which is crystalline is found as flat, plate-like particles with hexagonal morphology and irregular or angular when broken.
2. Amorphous graphite occurs as microcrystalline fine particles.
3. Vein graphite (lump graphite) occurs in veins or fractures and has the appearance of massive platy intergrowths of fibrous or acicular crystalline aggregates.
   Of the three types of carbon, amorphous carbon is structurally different from vein or flake graphite. Further, there are distinct morphological differences between vein and flake graphite.

### Flake Graphite

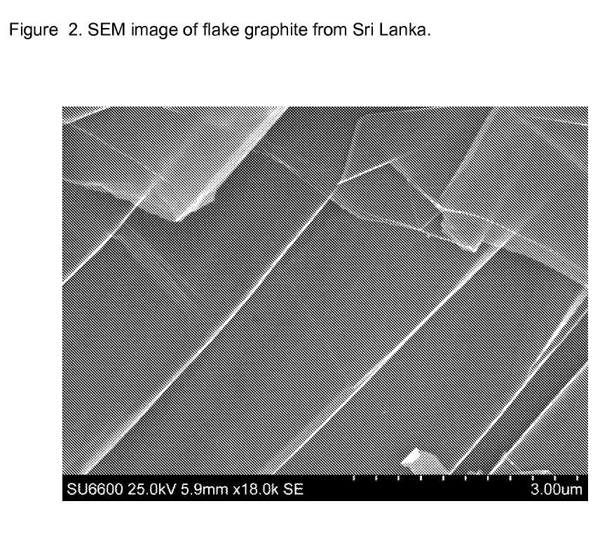

Flake graphite is found in metamorphic rocks uniformly distributed through the body of the ore or in concentrated lens shaped pockets. Flake graphite is removed by froth flotation and contains between 80 wt % to 90 wt % carbon. Flake graphite produced with greater than 98 wt % carbon purity, is obtained through chemical beneficiation processes. Flake graphite occurs in most parts of the world. Commercial grades are available in purities ranging from 80 wt % to 99.9 wt % carbon, and sizes from 2 to 800 μm. FIG. 2 shows the SEM image of an extracted flake graphite sample available from Bogala Mines, Sri Lanka.

### Vein Graphite

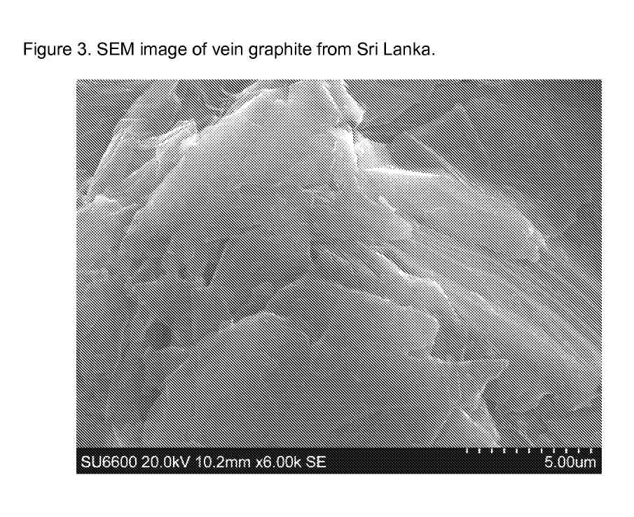

Vein graphite, also known as crystalline vein graphite, Sri Lankan graphite, or Ceylon graphite is a naturally occurring form of pyrolytic carbon. Vein graphite morphology ranges from flake-like for fine particles, needle or acicular for medium sized particles, and grains or lumps for very coarse particles. As the name implies, this form of graphite occurs as a vein mineral. Vein fillings range in thickness from 1 to 150 cm. Mined material is available in sizes ranging from fine powder to 10 cm lumps. Vein graphite has the highest degree of crystalline perfection of all conventional graphite materials. As a result of its high degree of crystallinity, vein graphite is utilized in electrical applications that require current carrying capacity. In friction applications, vein graphite is used in advanced brake and clutch formulations. Other applications include most of those that can utilize flake graphite. Commercial grades are available in purities ranging from 80 to 99 wt % carbon, and sizes from 3 μm powder to 8-10 cm lumps. FIG. 3 shows a SEM image of Sri Lankan vein graphite, available from Bogala Mines, Sri Lanka.

TABLE 1
Compositions and characteristics of
the anode and cathode materials

| Source of graphite | C (wt %)^{(a)} | C (atom %)^{(a)} |
|---|---|---|
| Vein graphite | 98.5 | 99.6 |
| Flake graphite | 93.8 | 96.5 |

^{(a)}Based on Energy Dispersive X-Ray Analysis (EDX)

FIG. 1, refers to a schematic view of an example of a fabrication setup for manufacturing CNTs. The setup contains electrodes comprising a vein graphite cathode (1) and a vein graphite anode (2). Attached to cathode and anode are circular hollow clamps (3) and (4); and jumper cables (5) and (6). Clamp (3) is connected to the positive terminal and clamp (4) is connected to the grounding terminal of a DC arc discharge power source. This discharge power source which is not shown in the diagram can supply 400 A at 100 V. The anode assembly [(2), (3) and (5)] and cathode assembly [(1), (4) and (6)] are connected to the smooth stainless steel guides [(7) and (8)]. These smooth stainless steel guides effectively provide for the cathode and anode assemblies to traverse linearly. The two assemblies are connected to a belt drive (9) which is traversed between the two pullies [(10) and (12)]. A DC servo motor (11) connects the driving pully (12) and the other pully (10). The anode and cathode assemblies, their guides and the driving mechanisms are mounted securely to a steel frame (13), which is fastened (14) to the vessel (15) to avoid any undesired motion. The gas inlet valve (16) is used to supply Argon (Ar) gas to the vessel, while the outlet valve (17) is used to remove air using a vacuum pump (not shown) and to purge the vessel with Ar gas.

Notably, the instant apparatus and method do not require the use of a magnetic field supplying device. Arc discharge methods such as Anazawa et al., 2009 U.S. Pat. No. 7,578,980 B2 require the use of an external magnetic field supplying device such as external permanent magnets or electromagnets generating a magnetic field that is thought to stabilize discharge by containing the discharge plasma within the magnetic field. For example, in Anazawa et al., 2009 U.S. Pat. No. 7,578,980 B2, it is preferable that the magnetic flux density in the magnetic field used to stabilize the discharge be no more than 1 T and no less than 10⁻⁵ T. In contrast, in the present invention, a magnetic field is not used to stabilize the discharge.

The carbon cathode according to the present invention is substantially the same dimensions as the carbon anode. While the absolute diameters of the cathode and anode are not particularly limited, the anode is preferably a cylindrical rod having a diameter of from 1 cm to 2 cm (0.4 in to 0.8 in) and the cathode is preferably a cylindrical rod having a diameter of at least 1.5 cm (0.6 in). The lengths of the anode and cathode are not particularly limited. As referred to herein the graphite pieces attached to the anode and the graphite pieces attached to the cathode are referred to as the cathode and anode. An electric current may be induced through the anode and the cathode by using a DC arc discharge power source. A gap of from about 1 mm to about 5 mm (0.04 in to 0.2 in), preferably from 1 mm to about 4 mm (0.04 in to 0.16 in), is maintained between the anode and the cathode throughout the process.

Electric currents are induced via the anode and the cathode in an inert gas atmosphere, such as Ar. Any inert gas that does not interfere with production of CNTs can be used. In an embodiment, room temperature inert gas is used. The inert atmosphere may contain minor amounts of other gases, such as hydrogen, nitrogen, or water, provided the other gases do not unacceptably interfere with the herein disclosed process. The inert gas may be recirculated and reused in preparing the CNTs. Further, the present disclosed process does not require a pressurized chamber and therefore, it is cost-effective and less dangerous.

Inducing an electric current through the anode and the cathode vaporizes the carbon anode, and forms a carbon deposit on the surface of the cathode. In experimental runs conducted by the inventors the carbon deposit is formed on the cathode as a circle of about 5 mm. The electric current is allowed to consume the anode. The carbon deposit material comprising CNTs may then be removed from the cathode and placed into, for example, a glass beaker. The collected carbonaceous material comprising CNTs in the glass beaker(s) is ground and purified. An advantage of CNTs produced herein is that extensive cleaning and purification is not required to obtain SWCNTs. In the purification steps CNTs were dispersed in aqueous solutions of sodium dodecylsulphate followed by sonication and filtration through fine membranes to obtain SWCNTs. (See Bonard et al., Adv. Mater, Vol. 9 (10), p. 827-831, (1997). CNTs produced may be characterized by using any of several analysis techniques, including, but not limited to, scanning electron microscopy (SEM), high resolution transmission electron microscopy (HRTEM), X-ray diffraction (XRD), energy loss spectroscopy (EELS), Raman spectroscopy (RS), and thermal gravimetric analysis (TGA).

A particular advantage of the process disclosed herein is that it does not require a cooling system for the electrodes; more particularly the cathode does not require external cooling by submerging it in water. It has been surprisingly found that using vein graphite as cathode and anode in the absence of external cooling mechanisms, or submerging the cathode in water, CNTs comprising SWCNTs were obtained. Purity of the Sri Lankan vein graphite anodes and cathodes used was about 99 wt %. Purity of the vein graphite can range from 97 wt % to 99 wt %.

Embodiment vein graphite, as mined, available from Bogala Mines, Sri Lanka, when analyzed by EDX indicated 99.74 wt % C; 0.18 wt % Al; 0.09 wt % Si. Another advantage is that vein graphite cathode and vein graphite anode can be used without extensive reshaping and/or polishing.

An embodiment process is carried out in a closed chamber whose volume is preferably 315 L and in an inert gas atmosphere. The inert gas comprises Ar, and can be recycled, and multiple productions of CNTs can be made. An advantage is that the process does not require high pressure or a vacuum chamber and can be carried out at atmospheric pressure.

Variation of process variables such as the applied voltage, current, arc duration and arcing gap can give desired types of conductive or semiconductive SWCNTs with varying sizes as required for different applications. Such SWCNTs, may (i) be conducting or semiconducting, (ii) have tunable bandgap, and (iii) have a very high current-carrying capacity; and these are suitable for a wide variety of electrical applications.

Embodiment arc currents are preferably below 60 A and most preferably below 35A. In certain embodiments arc duration to form the SWCNTs is preferably below 40 s. It is believed that SWCNTs are formed from the solid phase emanating from vapor; and the vein structure may act as the focal point of nanotube growth producing crystalline carbon nanoparticles as precursors for CNT growth. In an embodiment CNTs comprising SWCNTs along with MWCNTs can be formed without modifications to the electrodes. In certain embodiments SWCNTs are formed from Sri Lanka vein graphite in the absence of external cooling of the cathode or the anode during the formation of the SWCNTs. The process is allowed to reach ambient temperature of 25° C. for the CNTs containing SWCNTs to be observed. Such SWCNTs formed are preferably below 30 nm, more preferably below 20 nm and most preferably between 2 nm and 10 nm in diameter.

Embodiment SWCNTs having aspect ratios above 10,000 may be prepared using the herein disclosed process. Characteristics of the SWCNTs such as the aspect ratio can be changed by varying the arc current.

Embodiment SWCNTs having requisite semi-conductive properties that are suitable for electronic applications can also be obtained using the hereinabove process. As a person skilled in the art may recognize, yields of SWCNTs may be varied by changing the arc current, arc discharge time, and the gap between the anode and the cathode. Experimentally determined variables are that arc current is proportional to the length of the SWCNTs; and the yield of SWCNTs. The arc current is inversely proportional to the diameter of the produced SWCNTs. Further, care must be taken as an electrical current greater than 100 A can evaporate the electrodes without forming the SWCNTs. Arc discharge times greater than 40 s can lower the yield of the SWCNTs produced. Gaps between the electrodes lesser than 0.5 mm tend to produce SWCNTs with reduced aspect ratios than with larger gaps.

Embodiment SWCNTs can exhibit mechanical properties such as a Young's modulus of over 1 TPa, a stiffness equal to a diamond, and tensile strength of roughly 200 GPa. Due to their outstanding strength-to-weight ratio and high overall mechanical strength, they are suitable for a wide variety of mechanical applications, including composite structural materials for spacecrafts, cables, tethers, beams, heat exchangers, radiators, body armor, spacesuits, etc.

The following examples are presented for illustrative purposes only, and are not intended as a restriction on the scope of the invention.

### EXAMPLES

### Example 1

CNTs comprising SWCNTs were prepared using the apparatus described previously and shown in FIG. 1. A DC arc discharge power source rated for 400 A and 100 V was used to provide the electric current. An Ar gas delivery system was used to provide an inert atmosphere. A vein graphite piece (carbon purity of 99.7 wt %, as mined, available from Bogala Mines, Sri Lanka) was attached to the anode electrode. Another vein graphite piece (carbon purity of 99.7 wt %, available from Bogala Mines, Sri Lanka) was attached to the cathode electrode. The electrodes (cathode and anode) were traversed in a linear motion by means of a geared mechanism driven by a belt. The cathode and the anode were first brought together to initiate an arc and was then separated. The apparatus was housed in a 315 L vessel where a window was available to replace the electrodes; and the window was kept closed during the arc discharge. The following procedure was used to produce CNTs containing SWCNTs.
1. The vessel was purged to remove air using a vacuum pump until the pressure inside the vessel was reduced to −100 mmH₂O.
2. Ar gas was pumped using a vacuum pump into the vessel until the pressure equilibrated to atmospheric pressure.
3. Steps 1 and 2 were repeated three times to ensure sure that no active gas remained inside the vessel.
4. The DC power supply was switched on and the electrodes were moved towards each other such that the graphite pieces connected as anode and cathode made contact with each other. The electric arc was initiated when the electrodes contacted each other.
5. Once the electric arc was established in two to three seconds, the electrodes were moved apart by about 1 mm to 1.5 mm. The plasma generated thereupon was allowed to grow. After about 10 s from the electric arc initiation, the gap between the vein graphite pieces (connected to the electrodes) may be further increased by 1 mm to 2 mm, so as to allow sufficient room for the vaporized carbon from the vein graphite anode to be deposited on the vein graphite cathode.
6. The electrodes were allowed reach room temperature under Ar gas atmosphere without any external cooling source and CNTs containing SWCNTs were formed.
7. CNTs formed on the cathode which appeared as a dark ash colored circle of about 5 mm diameter surrounded by a black colored ring, were scratched off and separated from the cathode.
8. The CNTs produced contained at least 80% by weight of SWCNTs based on the carbonaceous material, and this material was then purified to separate the SWCNTs.
   Suitable conditions and electrode materials for the CNT manufacturing are shown in Table 2 and Table 3.

TABLE 2
Typical CNT manufacturing conditions obtained experimentally

| Parameter | Value | |
|---|---|---|
| Vessel volume | 315 | L |
| Inert gas | Ar | |
| Gas pressure | 1 | atm |
| DC voltage | 35 | V |
| DC current | 40 | A |
| Arc duration | 30 | s |

| | |
|---|---|
| Arc gap | 1 mm at start, 3 mm after 10 s |

Table 3 shows nature of the cathode and the anode and conditions of external cooling to obtain CNTs.

TABLE 3
Correlation between CNT quality, nature
of anode and nature of cooling

| Anode | Cathode | Cooling Mechanism | CNT Produced |
|---|---|---|---|
| flake graphite | vein graphite | no external cooling | No |
| vein graphite | vein graphite | no external cooling | Yes |
| flake graphite | flake graphite | no external cooling | No |
| vein graphite | flake graphite | no external cooling | No |

### Example 2

### CNT Growth Process

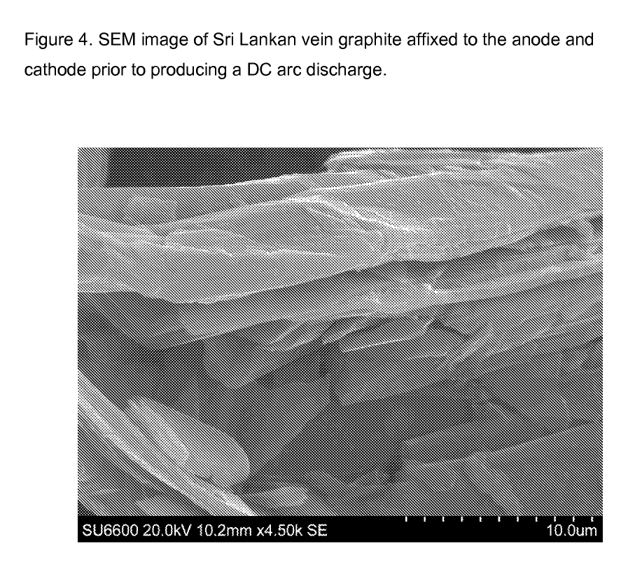

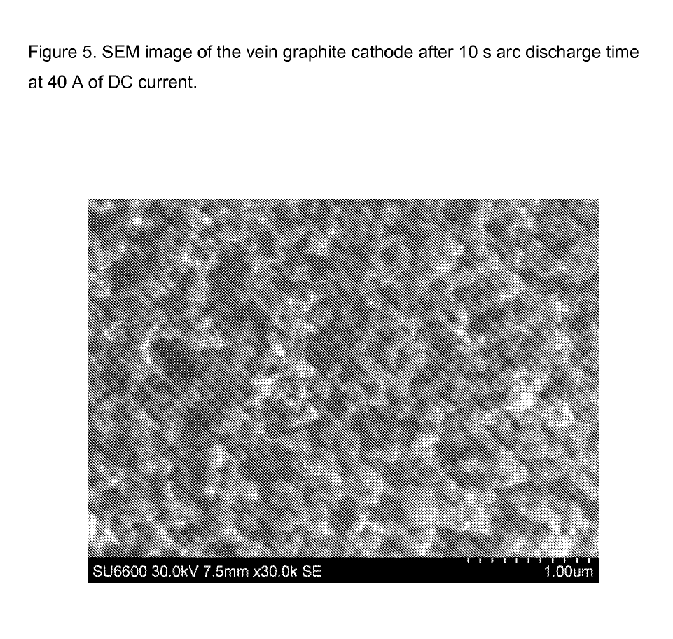

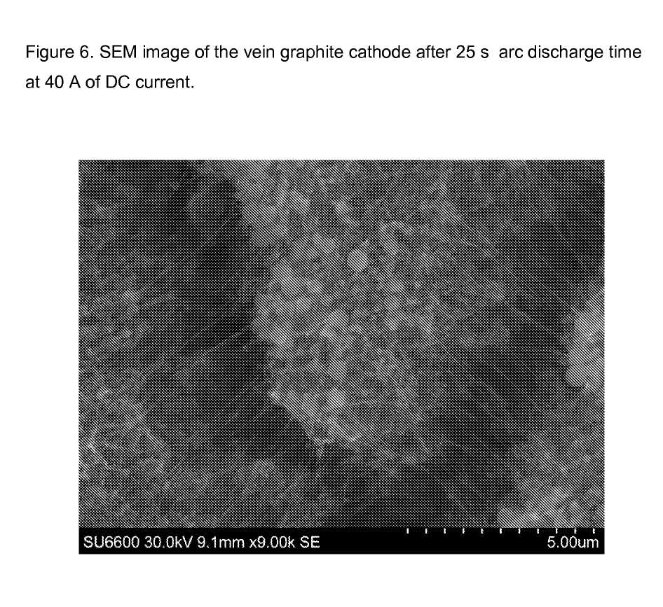

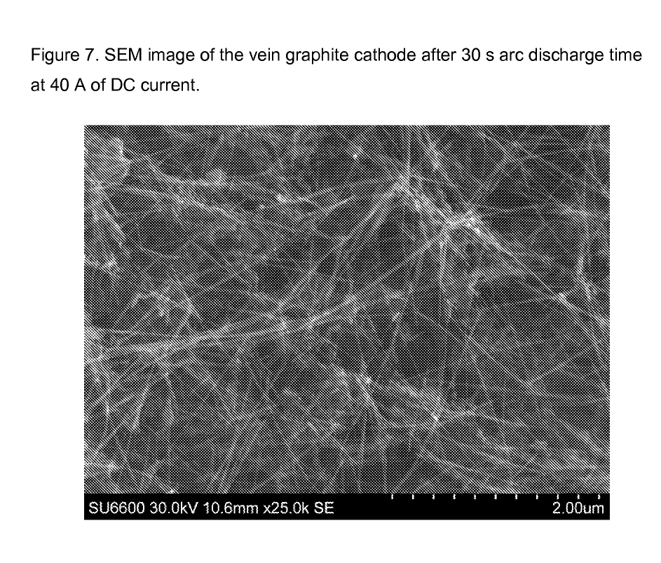

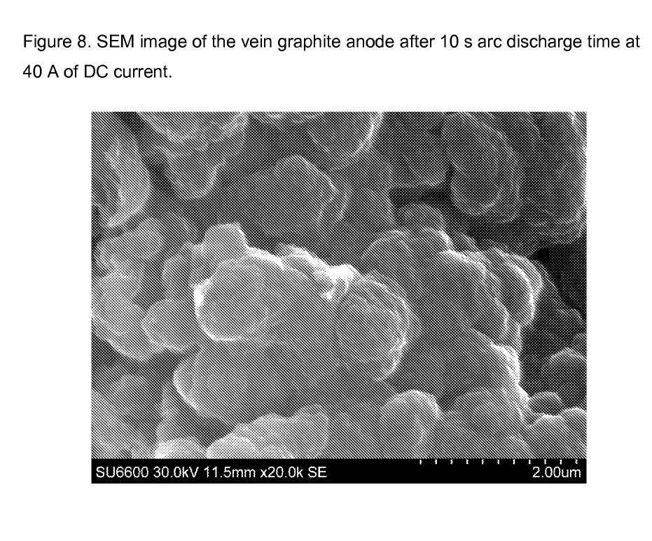

The CNT produced using the apparatus described previously and shown in FIG. 1 and the procedure in Example 1 were examined for changes in microstructure by using SEM. SEM images were obtained after the cathode or the anode was allowed to reach the ambient temperature of 25° C. in the Ar gas atmosphere. Vein graphite was used as the cathode and the following observations were made. During arc discharge the carbon in the cathode undergoes a phase change from crystalline phase to amorphous phase and produced carbon nanoparticles. These carbon nanoparticles were precursors to the formation and growth of CNTs containing SWCNTs. SEM images of the vein graphite cathode taken at intermediate stages of the process at various arc discharge times are shown in FIG. 5 through FIG. 7. FIG. 4 shows the SEM image of the vein graphite that was attached to the cathode prior to arc discharge, and FIG. 5 shows the SEM image of the vein graphite anode after 10 s of arc discharge time. Carbon nanoparticles were formed at the vein graphite cathode after 10 s of arc discharge time as seen from FIG. 5; and these nanoparticles nucleated CNT growth and acted as precursors for CNTs. FIG. 8 shows the SEM of the vein graphite anode after 10 s of arc discharge time. As seen from FIG. 6 through FIG. 7, CNT growth initiated by carbon nanoparticles continued since evaporated carbon was supplied from the arc energy associated with the heated anode. Moreover, as seen from FIG. 6 and FIG. 7, fibril structures corresponding to CNTs were observed throughout the image along with precursor carbon nanoparticles. Optimum yields of CNTs were obtained when 30 s of arc discharge time was used.

### Example 3

### Characterization of the Carbon Nanotubes

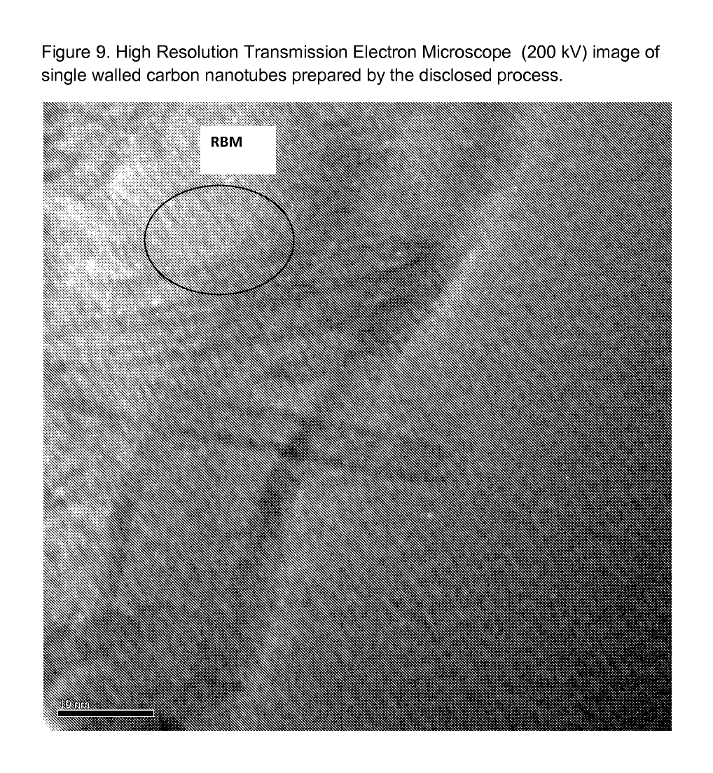

Both electron microscopy and Raman spectroscopy were used to examine the formation of the CNTs and SWCNTs. Existence of transparent walls in the Transmission Electron Microscope (TEM) image indicated that SWCNTs were formed. Raman spectroscopy showed the characteristic residual breathing mode RBM) below 500 cm⁻¹ confirming the presence of SWCNT in two samples prepared from the process of Example 1. Further, as seen from FIG. 9, High Resolution Transmission Electron Microscope (HRTEM) operated at 200 kV indicated the presence of SWCNTs.

That which is claimed:

1. A catalyst free process for manufacturing carbon nanotubes comprising:
a. providing a vein graphite anode and a vein graphite cathode in a closed vessel in the absence of a magnetic field supplying device;
b. inducing an electric current through the vein graphite anode and the vein graphite cathode in the absence of external cooling of the vein graphite anode or the vein graphite cathode;
c. providing an inert gas atmosphere to the closed vessel; and
d. producing carbon nanotubes on the vein graphite cathode.

2. The process of claim 1 wherein the carbon nanotubes comprise single walled carbon nanotubes.

3. The process of claim 1 wherein the vein graphite cathode has a purity of at least 99 wt % carbon.

4. The process of claim 1 wherein the vein graphite cathode and the vein graphite anode are substantially of the same size.

5. The process of claim 1, wherein the process comprises maintaining a gap from about 1 mm to about 5 mm between the vein graphite anode and the vein graphite cathode during the arc discharge.

6. The process of claim 1 wherein steps (a) through (d) are performed at substantially atmospheric pressure.

7. The process of claim 1 wherein the inert gas is recycled.

8. The process of claim 1, further comprising the steps of removing, grinding, and purifying the deposit formed on the vein graphite cathode, thereby forming a purified carbonaceous material.

9. The process of claim 8, wherein the purified carbonaceous material contains single-walled carbon nanotubes (SWCNTs).

10. The process of claim 1 wherein the inert gas is Argon.

11. A catalyst free process for manufacturing carbon nanoparticle precursors for carbon nanotube growth comprising:
a. providing a vein graphite anode and a vein graphite cathode in a closed vessel in the absence of a magnetic field supplying device;
b. inducing an electric current through the vein graphite anode and the vein graphite cathode in the absence of external cooling of the vein graphite anode or the vein graphite cathode;
c. providing an inert gas atmosphere to the closed vessel; and
d. forming carbon nanoparticle precursors for carbon nanotube growth.

12. An apparatus for manufacturing carbon nanotubes in the absence of external cooling and comprising:
a. a catalyst free carbon anode comprising vein graphite and a catalyst free carbon cathode comprising vein graphite in the absence of a magnetic field supplying device; and
b. a DC arc discharge power source comprising a positive terminal and a grounding terminal; wherein said catalyst free carbon anode is operably connected to said positive terminal of the DC arc discharge power source and said catalyst free carbon cathode is operably connected to said grounding terminal of the DC arc discharge power source.
